(19) United States
(12) Patent Application Publication
(10) Pub. No.: US 2008/0224795 A1
(43) Pub. Date: Sep. 18, 2008

(54) ACTIVE BALUN

(75) Inventors: Kyu-don CHOI, Yongin-si (KR); Choong-yul CHA, Yongin-si (KR); Heung-bae LEE, Seongnam-si (KR); Sung-jae JUNG, seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD, Suwon-si (KR)

(21) Appl. No.: 11/756,916

(22) Filed: Jun. 1, 2007

(30) Foreign Application Priority Data
Jan. 16, 2007 (KR) 2007-4784

(51) Int. Cl. H03H 5/00

(52) U.S. Cl. 333/25

(57) ABSTRACT

An active balun for improving a phase matching characteristic includes a transistor part which has an input terminal receiving an input signal and first and second output terminals which output signals corresponding to the input signal, and a capacitance matching part provided on the side of one of the first and second output terminals which matches capacitances as seen from the first and second output terminals. The capacitance matching part may be composed of a transistor which bleeds a current from the one output terminal.

### CROSS-REFERENCE TO RELATED APPLICATIONS

This application claims priority from Korean Patent Application No. 10-2007-0004784, filed on Jan. 16, 2007, in the Korean Intellectual Property Office, the disclosure of which is incorporated herein by reference in its entirety.

### BACKGROUND OF THE INVENTION

1. Field of the Invention

The present invention relates to an active balun, and more particularly, to an active balun capable of matching capacitances as seen from two output terminals to improve a phase matching characteristic.

2. Description of the Related Art

The term ‘balun’ is a generic name for circuits or structures that convert between unbalanced and balanced signals. Many RF systems have components including balanced (differential) lines, for example, a mixer or a surface acoustic wave (SAW) filter. In order to connect such a component to an amplifier having an unbalanced line (single-ended) line, a balun is required.

A balun comprises one input terminal to which an unbalanced signal is input and two output terminals from which unbalanced signals, that is, differential signals are output. The characteristics of a balun depend on an amplitude difference and a phase difference between signals output from two output terminals. Ideally, a balun provides two differential signals having the same amplitude and a phase difference of 180°. The smaller the amplitude difference between the two output signals, the better a gain matching characteristic of the balun. Further, as the phase difference between the two output signals approaches 180°, a phase matching characteristic of the balun improves.

However, usage of an active balun may cause an increase in phase error of differential signals in a high frequency band. Also, the increase in phase error may degrade the performance of an analog circuit used at the next stage of the balun. For this reason, an active balun having an improved phase matching characteristic in a high frequency band is required.

Active baluns of various structures have been devised. One active balun is disclosed in U.S. Pat. No. 6,922,108. The disclosed balun uses an inductor provided in a chip to reduce phase error. However, the size of the inductor increases the size of the chip. Further, due to a narrow band characteristic of the inductor, the balun has difficulty for use in processing broadband signals. Further, the balun was designed as a structure based on a differential amplifier. Therefore, the power consumption of the balun is twice that of a balun using a single-ended amplifier. Consequently, the structure of the balun disclosed in U.S. Pat. No. 6,922,108 is not suitable for subminiature devices for broadband communication.

Another balun using a plurality of transistors is disclosed in Japanese Patent Publication No. 2001-85973.

FIG. 1 is a drawing included in Japanese Patent Publication No. 2001-85973. Referring to FIG. 1, a balun comprises a plurality of resistors 11, 21, and 31, a plurality of transistors 12, 22, and 32, a constant current source 13, and a bias circuit 14. Japanese Patent No. 2001-85973 discloses the following: (1) the phase of an input of each of common source transistors, that is, the transistors 12 and 32 is different from the phase of an output of the corresponding transistor, and (2) the phase of an input of a common gate transistor, that is, the transistor 22 is the same as the phase of an output of the corresponding transistor. Specifically, where an input signal is applied to the balun, a first transistor, that is, the transistor 12 changes the phase of the input signal by 180° and the changed signal is output as a first output signal from a first output terminal of the balun. The first output terminal is connected to a drain terminal of the first transistor 12. Meanwhile, the phase of the input signal is changed by second and third transistors, that is, the transistors 22 and 32 respectively. The changed signal has the same phase as the input signal and is output as a second output signal from a second output terminal of the balun.

The disclosed balun does not use inductors. Therefore, the balun is smaller than a balun using an inductor. However, since the balun has two or more current paths, the power consumption of the balun is large. Further, the balun uses a number of transistors 12, 22, and 32. In this case, characteristics of the transistors 12, 22, and 32 may not match one another. The characteristic mismatching may cause an increase in phase error. Furthermore, nonlinear characteristics of the transistors may considerably degrade linearity of the balun.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above. Accordingly, the present general inventive concept has been made to solve the above-mentioned and/or problems.

Apparatuses of the present invention provide an active balun that can achieve capacitance matching between output terminals, thereby improving a phase matching characteristic in a high frequency band.

Apparatuses of the present invention also provide an active balun that can bleed a current from one output terminal to achieve capacitance matching and to improve linearity.

According to an aspect of the present invention, there is provided an active balun, which comprises: a transistor part which has an input terminal which receives an input signal and first and second output terminals which output signals corresponding to the input signal; and a capacitance matching part provided on one of the first and second output terminals which matches capacitances connected to the first and second output terminals.

In the active balun, the capacitance matching part may comprise a current source which bleeds a current from the one output terminal to cause a capacitance at the one output terminal, thereby matching a capacitance connected the one output terminal to a capacitance connected the other output terminal.

In the above-mentioned structure, the current source may be a transistor connected to the one output terminal.

According to another aspect of the present invention, the capacitance matching part may be a capacitor connected to the one output terminal.

According to another aspect of the present invention may further comprise: a first resistor provided on the first output terminal; and a second resistor provided on the second output terminal. In this structure, at least one of the first and second resistors may be a variable resistor.

According to another aspect of the present invention, the transistor part may be a bipolar transistor or a metal-oxide-semiconductor (MOS) transistor.

### BRIEF DESCRIPTION OF THE DRAWINGS

The above and/or other aspects of the present invention will be more apparent by describing certain exemplary embodiments of the present invention with reference to the accompanying drawings, in which:

FIG. 1 is a circuit diagram illustrating the structure of an active balun disclosed in Japanese Patent Publication No. 2001-85973;

FIG. 2 is a block diagram illustrating the structure of an active balun according to an exemplary embodiment of the present invention;

FIGS. 3 to 8 are circuit diagrams illustrating various active baluns according to exemplary embodiments of the present invention;

FIG. 9 is a circuit diagram schematically illustrating the structure of a variable resistor used in each of the exemplary embodiments of the present invention;

FIG. 10 is a circuit diagram where specific element values are applied to simulate specific characteristics of an active balun according to an exemplary embodiment of the present invention;

FIG. 11 is a graph illustrating a phase difference between output signals of the circuit shown in FIG. 10 and a phase difference between output signals of a circuit having the same structure as FIG. 10 but without a capacitance matching part; and

FIGS. 12 and 13 are graphs for explaining a linearity improving effect due to a capacitance matching part.

### DETAILED DESCRIPTION OF THE EXEMPLARY EMBODIMENTS

Certain exemplary embodiments of the present invention will now be described in greater detail with reference to the accompanying drawings.

In the following description, same drawing reference numerals are used for the same elements even in different drawings. The matters defined in the description, such as detailed construction and elements, are provided to assist in a comprehensive understanding of the present invention. Thus, it is apparent that the present invention can be carried out without those specifically defined matters. Also, well-known functions or constructions are not described in detail since they would obscure the invention with unnecessary detail.

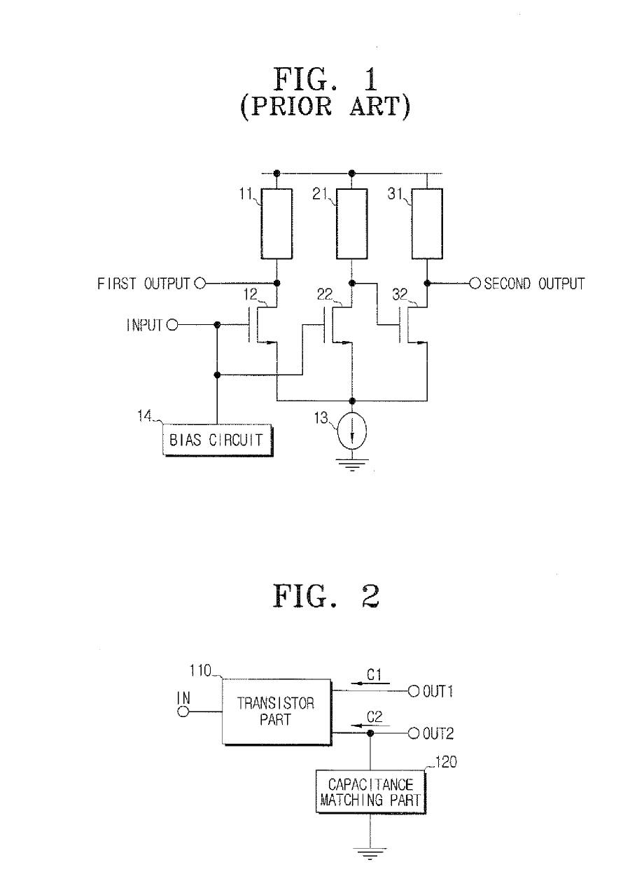

FIG. 2 is a block diagram illustrating the structure of an active balun according to an exemplary embodiment of the present invention. Referring to FIG. 2, an active balun according to an exemplary embodiment of the present invention comprises a transistor part 110 and a capacitance matching part 120.

The transistor part 110 has one input terminal IN and first and second output terminals OUT1 and OUT2. According to an input signal input through the input terminal, the transistor part 110 outputs differential output signals through the first and second output terminals. The transistor part 110 is designed to make the amplitudes of the differential output signals same and make the phases of the differential output signals different from each other by 180°.

Where the transistor part 110 is biased, the transistor part 110 outputs differential output signals through the first and second output terminals. In this procedure, a capacitance component is generated at each of the output terminals. The capacitance component may influence the phases of the output signals. As a result, the difference between the phases of the differential output signals may be adjusted to 180°.

The capacitance matching part 120 is provided on one of the output terminals and supplies a specified capacitance component, which functions to match the capacitance connected to the first output terminal and the capacitance connected to the second output terminal.

As shown in FIG. 2, it is assumed that the capacitance including a parasitic capacitance value as seen from the first output terminal is denoted by C1, the capacitance including a parasitic capacitance value as seen from the second output terminal is denoted by C2, and a capacitance value obtained by subtracting the capacitance C2 from the capacitance C1 is denoted by Cp. In this case, the capacitance matching part 120 supplies the capacitance value Cp to match the capacitances as connected to the first and second output terminals. Accordingly, the output signals output from the first and second output terminals have a phase difference of 180°. The capacitance value Cp may be set through simulations in an active balun manufacturing process. In FIG. 2, the capacitance matching part 120 is provided on the second output terminal OUT2; however, the capacitance matching part 120 may be provided on the first output terminal OUT1.

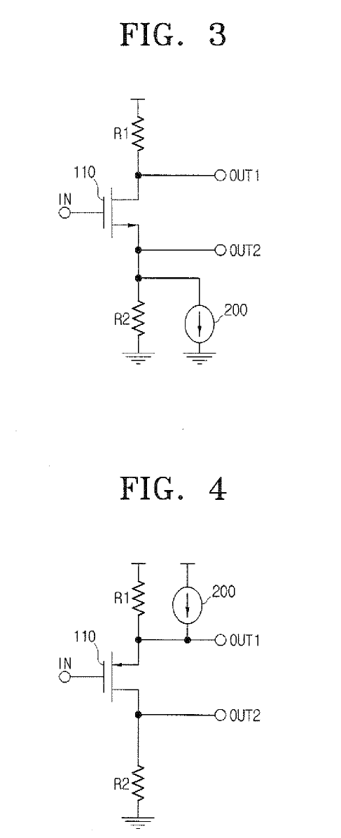

FIG. 3 is a circuit diagram illustrating the circuit structure of the active balun shown in FIG. 1 in detail. Referring to FIG. 3, the transistor part 110 comprises a MOS transistor in which a gate terminal serves as the input terminal and source and drain terminals serve as the first and second output terminals, respectively. Resistors R1 and R2 each having a specified resistance value are connected to the source and drain terminals, respectively. Further, the capacitance matching part 120 is composed of a current source 200.

The current source 200 is connected to the source terminal in parallel. The current source 200 partially bleeds some of the current output from the second output terminal OUT2, causing certain parasitic capacitance. Therefore, the combined capacitance of the parasitic capacitance caused by the current source 200 and the capacitance connected to the second output terminal OUT2 becomes equal to the capacitance connected to the first output terminal OUT1. Consequently, capacitance matching is achieved, whereby the phase matching characteristic is improved.

FIG. 4 shows a structure where the current source 200 is provided on the first output terminal OUT1. As shown in FIG. 4, where the transistor part 110 is composed of a p-type MOS (PMOS) transistor, the current source 200 is connected on the first output terminal OUT1 and supplies a capacitance component to the first output terminal.

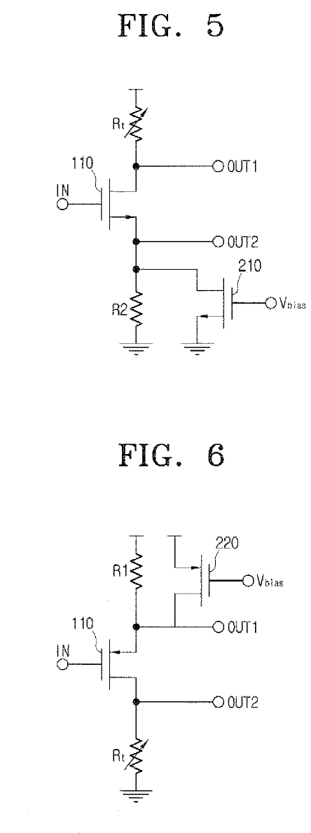

FIG. 5 is a circuit diagram illustrating a similar structure to that shown in FIG. 3 except that the current source 200 is composed of a MOS transistor 210 and the resistor R1 is replaced with a variable resistor Rt. The resistances of the resistors connected to the output terminals determine the amplitudes of the differential output signals. For this reason, where the variable resistor Rt is connected to the first output terminal or the second output terminal, the resistance value of the variable resistor may be controlled to adjust the amplitude of one of the differential output signals. Therefore, it is possible to improve a gain matching characteristic between the first and second output terminals OUT1 and OUT2.

In FIG. 5, where the MOS transistor 210 is turned on by a bias power supply Vbias, it bleeds current output through the second output terminal toward a source of the MOS transistor 210. Accordingly, capacitance is generated on the second output terminal OUT2, thereby achieving capacitance matching between the first and second output terminals.

FIG. 6 is a circuit diagram illustrating a similar structure to that shown in FIG. 4 except that the current source 200 is composed of a PMOS transistor 220 and the resistor R2 is replaced with a variable resistor Rt. Referring to FIG. 6, the PMOS transistor 220 serves as the current source 200 so as to supply a parasitic capacitance.

Where the capacitance matching part 120 is composed of the transistor 210 or 220 as shown in FIGS. 5 and 6, the phase matching characteristic is improved and linearity is also improved. The linearity improving effect will be described below.

FIG. 7 is a circuit diagram illustrating a similar structure to that shown in FIG. 3 except that the capacitance matching part 120 is composed of a capacitor 300. Referring to FIG. 7, the capacitor 300 is connected on the second output terminal OUT2 in parallel. The capacitor 300 increases the capacitance connected to the second output terminal so as to match the capacitances as shown from the first and second output terminals. As a result, the phase difference between the differential output signals is maintained at 180°. In the structure shown in FIG. 7, at least one of the resistors R1 and R2 may be a variable resistor to adjust the amplitude of at least one of the differential signals output from the first and second output terminals.

In the above-mentioned exemplary embodiments, the transistor is a MOS transistor; however, a bipolar transistor may be used.

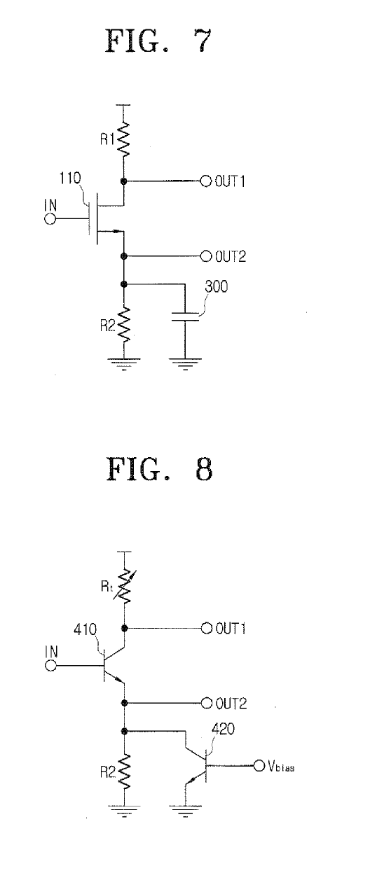

FIG. 8 is a circuit diagram illustrating a similar structure to that shown in FIG. 5 except that the transistors constituting the transistor part and the capacitance matching part are replaced with bipolar transistors 410 and 420. The operation of each of the bipolar transistors 410 and 420 is the same as the MOS transistors shown in FIG. 5.

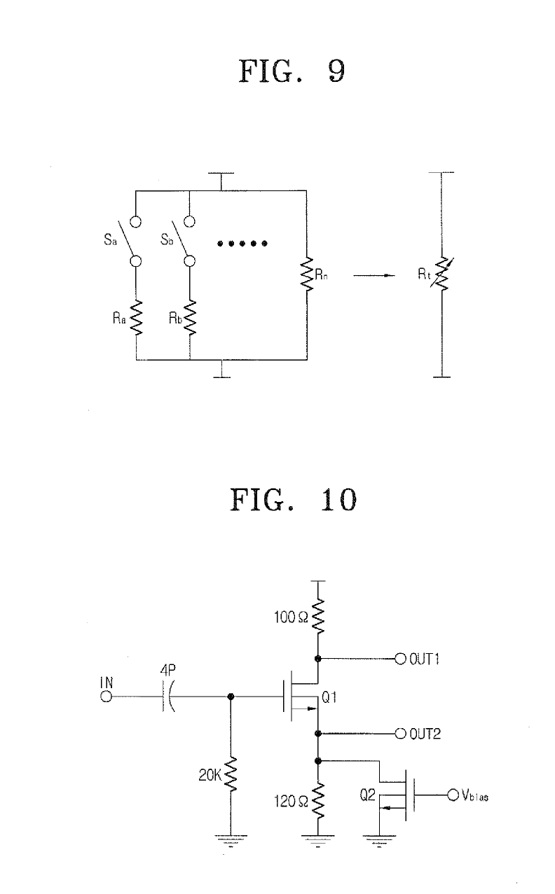

FIG. 9 is a circuit diagram schematically illustrating the structure of the variable resistor used in each of the above-mentioned exemplary embodiments. Referring to FIG. 9, the variable resistor has a path formed by a resistor Rn and a plurality of paths formed by connecting a plurality of resistors Ra, Rb, . . . , and Rn-1 in series with a plurality of switches Sa, Sb, . . . , and Sn-1, respectively. Where all of the switches Sa to Sn-1 are turned on, the variable resistor Rt has a combined resistance of the resistors Ra to Rn. Meanwhile, where all of the switches Sa to Sn-1 are turned off, the variable resistor Rt has the resistance of the resistor Rn. Whether to turn on or off each of the switches may be controlled by a central processing part (not shown), which will be separately provided. More specifically, the central processing part monitors the amplitudes of the differential output signals output from the first and second output terminals. When determining that the amplitudes of the differential output signals are different from each other, the central processing part controls the resistance of the variable resistor provided on at least one of the first and second output terminals to perform amplitude adjustment, thereby improving the gain matching characteristic.

FIG. 10 is a circuit diagram where specific element values are applied to simulate specific characteristics of an active balun according to an exemplary embodiment of the present invention. Referring to FIG. 10, an input resistor whose resistance is 20 KΩ and a capacitor whose capacitance is 4 pF are connected to a gate terminal of a transistor Q1 serving as the transistor part 110. Resistors having resistances of 100 Ω and 120 Ω are used as the resistors R1 and R2, respectively. An n-type MOS (nMOS) transistor Q2 serves as the capacitance matching part 120.

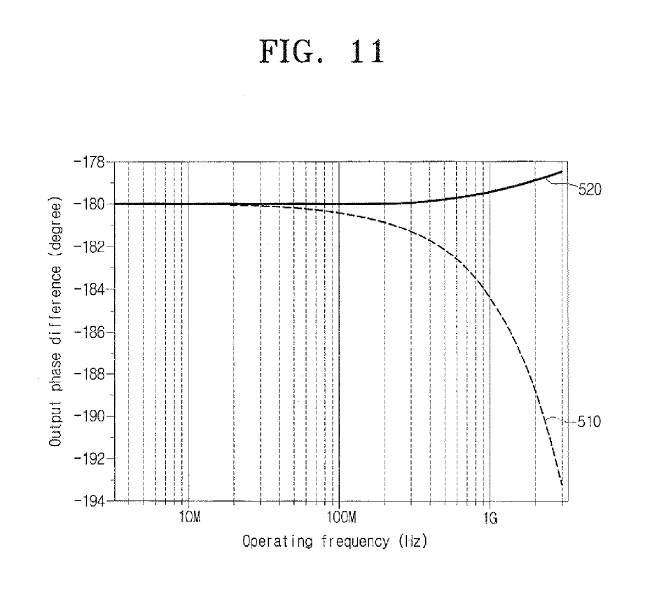

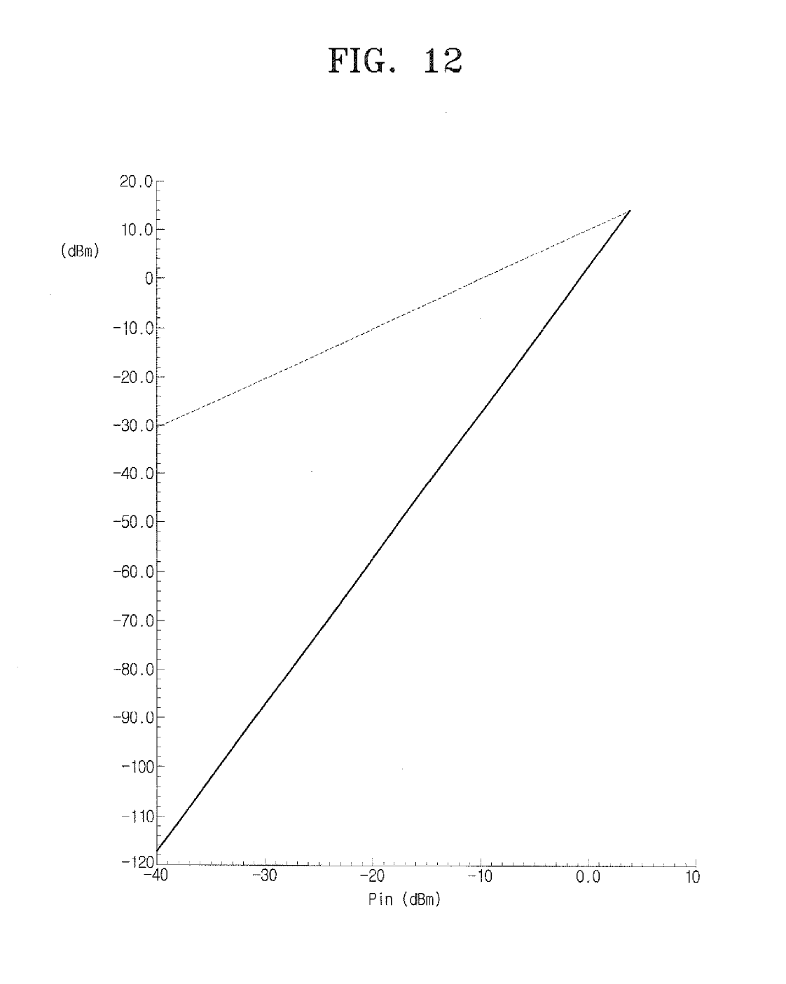

FIG. 11 is a graph illustrating the results obtained by simulating the relationship between a frequency and a phase difference in the circuit shown in FIG. 10 and the relationship between a frequency and a phase difference in a circuit having a similar structure to the circuit shown in FIG. 10 except that it does not have the nMOS transistor Q2.

In FIG. 11, a first curve 510 represents the simulation result where the nMOS transistor Q2 does not exist in the circuit shown in FIG. 10, and a second curve 520 represents the result where the nMOS transistor Q2 exists in the circuit shown in FIG. 10. In each of the first curve 510 and the second curve 520, where the frequency is about 50 MHz or less, the phase difference between the differential output signals is almost maintained at 180°. However, in the first curve 510, where the frequency exceeds 50 MHz, as the frequency increases, the phase difference increases. For example, at a frequency of 1 GHz, the phase difference is about 185.5°.

In contrast, in the second curve 520, even when the frequency is in a range equal to or more than 1 GHz, a variation in the phase difference is less than about 1°. In other words, in the second curve 520, the phase difference between the differential output signals is substantially maintained at 180°even in a high frequency band.

FIG. 12 is a graph illustrating the relationship between an input power and an output power to define linearity where the nMOS transistor Q2 does not exist in the circuit shown in FIG. 10. From FIG. 12, a third order input intercept point IIP3 can be seen. The third order input intercept point IIP3 is one of variables used to define linearity of an amplifier. The larger the value of the third order input intercept point IIP3 is, the better the linearity of the amplifier is. More specifically, the third order input intercept point IIP3 is the point at which the power in the third-order product and the basic tone power intersect, when the amplifier is assumed to be linear. In FIG. 12, a dotted line represents a basic tone power and a solid line represents the third-order product. The two lines intersect at about 3.5 dBm and the third order input intercept point IIP3 is thus about 3.5 dBm.

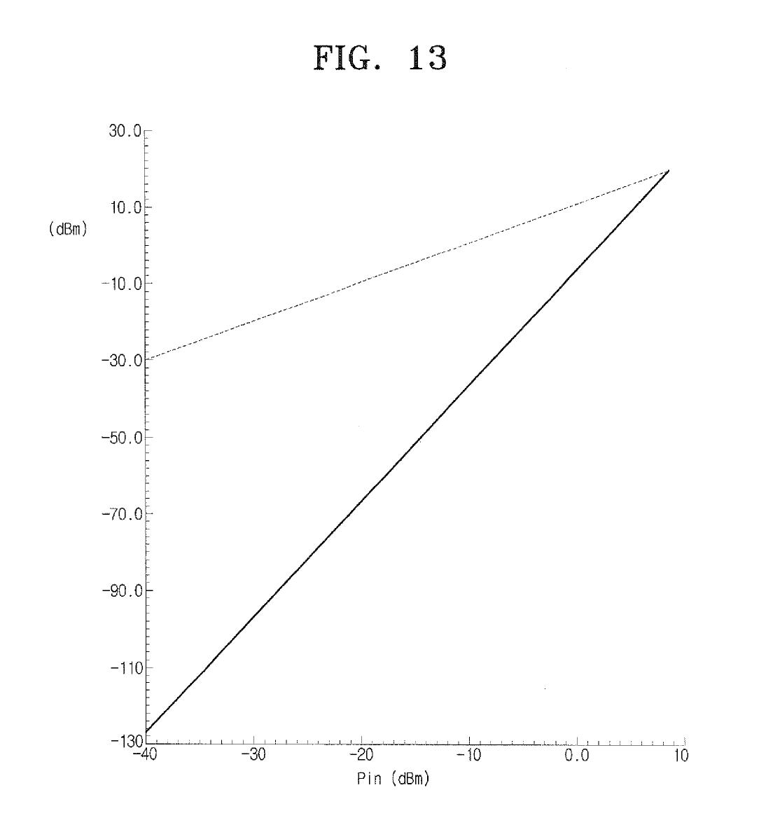

FIG. 13 is a graph illustrating the relationship between an input power and an output power to define linearity of the circuit shown in FIG. 10. Referring to FIG. 13, a dotted line and a solid line intersect at about 8.5 dBm and the third order input intercept point IIP3 is thus about 8.5 dBm. The third order input intercept point IIP3 is different from that shown in FIG. 12 by about 5 dBm. In other words, usage of the nMOS transistor Q2 remarkably improves the linearity.

As described above, according to the exemplary embodiments of the present invention, the capacitance matching between the output terminals can be achieved to adjust the phase difference between the output signals as closer as possible to 180°. As a result, the phase matching characteristic is remarkably improved. Further, usage of the variable resistor improves the gain matching characteristic and the linearity of the active balun. In addition, it is possible to improve the phase matching characteristic in a high frequency band without using any inductors. Therefore, it is possible to reduce the size and power consumption of the active balun. Also, the active balun can be mounted on a chip, and a balun effect is achieved without various kinds of external elements, such as a passive balun.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. An active balun comprising:
a transistor part which has an input terminal which receives an input signal and first and second output terminals which output signals corresponding to the input signal; and
a capacitance matching part provided on one of the first and second output terminals which matches capacitances connected to the first and second output terminals.

2. The active balun as claimed in claim 1, wherein the capacitance matching part comprises a current source which bleeds a current from one output terminal to cause a capacitance at the one output terminal, thereby matching a capacitance connected to the one output terminal to a capacitance connected to the other output terminal.

3. The active balun as claimed in claim 2, wherein the current source is a MOS transistor connected to the one output terminal.

4. The active balun as claimed in claim 1, wherein the capacitance matching part is a capacitor connected to the one output terminal.

5. The active balun as claimed in claim 1, further comprising:
a first resistor provided on the first output terminal; and
a second resistor provided on the second output terminal,
wherein at least one of the first and second resistors is a variable resistor.

6. The active balun as claimed in claim 2, further comprising:
a first resistor provided on the first output terminal; and
a second resistor provided on the second output terminal,
wherein at least one of the first and second resistors is a variable resistor.

7. The active balun as claimed in claim 4, further comprising:
a first resistor provided on the first output terminal; and
a second resistor provided on the second output terminal,
wherein at least one of the first and second resistors is a variable resistor.

8. The active balun as claimed in claim 1, wherein the transistor part is a MOS transistor.

9. The active balun as claimed in claim 1, wherein the transistor part is a bipolar transistor.

10. The active balun as claimed in claim 2, wherein the current source is a bipolar transistor connected to the one output terminal.
